(19) United States
(12) Patent Application Publication
(10) Pub. No.: US 2025/0292821 A1
(43) Pub. Date: Sep. 18, 2025

(54) Multiple-Row Refresh for Usage-Based Disturbance Mitigation

(71) Applicant: Micron Technology, Inc., Boise, ID (US)

(72) Inventor: Yang Lu, Boise, ID (US)

(73) Assignee: Micron Technology, Inc., Boise, ID (US)

(21) Appl. No.: 19/042,519

(22) Filed: Jan. 31, 2025

Related U.S. Application Data
(60) Provisional application No. 63/566,761, filed on Mar. 18, 2024.

(51) Int. Cl. G11C 11/406; G11C 11/408; G11C 11/4091

(52) U.S. Cl. CPC G11C 11/40622; G11C 11/40603; G11C 11/4087; G11C 11/4091

(57) ABSTRACT

Apparatuses and techniques for implementing multiple-row refresh for usage-based disturbance mitigation are described. Multiple-row refresh for usage-based disturbance mitigation involves refreshing at least one victim row for usage-based disturbance mitigation during a refresh operation that involves another row. The victim row and the other row are effectively refreshed in parallel. Possible victim rows that can be refreshed can be coupled to components that are not shared by the other row associated with the refresh operation. Any count update procedures associated with refreshing the victim row and the other row can be performed at different times to avoid potential conflict on global input/output lines. Refreshing a victim row during a refresh operation of another row allows for refreshing extra victim rows.

### CROSS-REFERENCE TO RELATED APPLICATION(S)

This application claims the benefit of U.S. Provisional Patent Application Ser. No. 63/566,761 filed on Mar. 18, 2024, the disclosure of which is incorporated by reference herein in its entirety.

### BACKGROUND

Computers, smartphones, and other electronic devices rely on processors and memories. A processor executes code based on data to run applications and provide features to a user. The processor obtains the code and the data from a memory. The memory in an electronic device can include volatile memory (e.g., random-access memory (RAM)) and non-volatile memory (e.g., flash memory). Like the capabilities of a processor, the capabilities of a memory can impact the performance of an electronic device. This performance impact can increase as processors are developed that execute code faster and as applications operate on increasingly larger data sets that require ever-larger memories.

### BRIEF DESCRIPTION OF THE DRAWINGS

Apparatuses of and techniques for implementing multiple-row refresh for usage-based disturbance mitigation are described with reference to the following drawings. The same numbers are used throughout the drawings to reference like features and components:

FIG. 1 illustrates example apparatuses that can implement aspects of multiple-row refresh for usage-based disturbance mitigation;

FIG. 2 illustrates an example computing system that can implement aspects of multiple-row refresh for usage-based disturbance mitigation within a memory device;

FIG. 3 illustrates an example memory device in which aspects of multiple-row refresh for usage-based disturbance mitigation may be implemented;

FIG. 4 illustrates an example bank in which aspects of multiple-row refresh for usage-based disturbance mitigation can be implemented;

FIG. 5 illustrates an example timing diagram of a memory device implementing one or more aspects of multiple-row refresh for usage-based disturbance mitigation;

FIG. 6 illustrates an example bank in which aspects of multiple-row refresh for usage-based disturbance mitigation can be implemented;

FIG. 7 illustrates an example timing diagram of a memory device implementing one or more aspects of multiple-row refresh for usage-based disturbance mitigation;

FIG. 8 illustrates an example relationship between a read-write circuit and sections of a bank in which aspects of multiple-row refresh for usage-based disturbance mitigation may be implemented; and

FIG. 9 illustrates an example method for implementing aspects of multiple-row refresh for usage-based disturbance mitigation.

### DETAILED DESCRIPTION

### Overview

Processors and memory work in tandem to provide features to users of computers and other electronic devices. As processors and memory operate more quickly together in a complementary manner, an electronic device can provide enhanced features, such as high-resolution graphics and artificial intelligence (AI) analysis. Some applications, such as those for financial services, medical devices, and advanced driver assistance systems (ADAS), can also demand more-reliable memories. These applications use increasingly reliable memories to limit errors in financial transactions, medical decisions, and object identification. However, in some implementations, more-reliable memories can sacrifice bit densities, power efficiency, and simplicity.

Processors and memories can be secured to a printed circuit board (PCB), such as a rigid or flexible motherboard. The PCB can include sockets for receiving at least one processor and one or more memory devices. Wiring infrastructure can be disposed on at least one layer of the PCB, enabling communication between two or more components. Some PCBs include multiple sockets that are each shaped as a linear slot designed to accept a dual in-line memory module (DIMM) (e.g., a memory device). These sockets can be fully occupied by dual in-line memory modules while a processor is still able to utilize additional memory. In such situations, the system is capable of greater performance if additional memory is available to the processor.

PCBs may also include at least one peripheral component interconnect express (PCIe®) slot. A PCIe slot is designed to provide a common interface for various types of components that may be coupled to a PCB. The PCIe protocol can provide higher rates of data transfer, smaller footprints, or both to the PCB compared to some other standards. Accordingly, certain PCBs enable a processor to access a memory device that is connected to the PCB via a PCIe slot.

To meet the demands for physically smaller memories, memory devices can be designed with higher chip densities. Increasing chip density, however, can increase the electromagnetic coupling (e.g., capacitive coupling) between adjacent or proximate rows, such as word lines, of memory cells due, at least in part, to a shrinking distance between these rows. With this undesired coupling, activation (or charging) of a first row of memory cells can sometimes negatively impact a second nearby row of memory cells. In particular, activation of the first row can generate interference, or crosstalk, that causes the second row to experience a voltage fluctuation. In some instances, this voltage fluctuation can cause a state (or value) of a memory cell in the second row to be incorrectly determined by a sense amplifier. Consider an example in which a state of a memory cell in the second row is a “1”. In this example, the voltage fluctuation can cause a sense amplifier to incorrectly determine the state of the memory cell to be a “0” instead of a “1”. Left unchecked, this interference can lead to memory errors or data loss within the memory device.

In some circumstances, a particular row of memory cells is activated repeatedly in an unintentional or intentional (sometimes malicious) manner. Consider, for instance, that memory cells in an R^{th} row are subjected to repeated activation, which causes one or more memory cells in an adjacent row (e.g., within an R+1 row, an R+2 row, an R−1 row, and/or an R−2 row) to change states. This effect is referred to as a usage-based disturbance. The occurrence of usage-based disturbance can lead to the corruption or changing of contents within the affected victim row of memory.

Some memory devices utilize circuits that can detect usage-based disturbance and perform operations to mitigate its effects. For example, a usage-based disturbance mitigation pump can be included as one of the pumps provided by a normal refresh command. Further increases in chip density will require more usage-based disturbance mitigation operations to ensure enough usage-based disturbance mitigation is performed to refresh each victim row. However, tight timing and power requirements may hinder the ability to execute all of the usage-based disturbance pumps included with normal refresh commands, much less provide additional usage-based disturbance mitigation operations. For example, additional mitigation operations performed after normal or scheduled mitigation refresh operations can slow down performance by taking time away from regular memory access operations. Also, performing these additional refreshes utilizes additional power, which make it challenging to integrate within power-constrained devices.

To address this and other issues regarding usage-based disturbance, this document describes aspects of multiple-row refresh for usage-based disturbance mitigation. Multiple-row refresh for usage-based disturbance mitigation involves refreshing at least one victim row for usage-based disturbance mitigation during another refresh operation that involves another row. The victim row and the other row are effectively refreshed in parallel. Possible victim rows that can be refreshed for usage-based disturbance mitigation can be coupled to components that are not shared by the other row associated with the other refresh operation. To elaborate, the victim row and the other row can be coupled to different digit/column/bit lines and/or sense amplifiers. Any additional usage-based disturbance mitigation procedures associated with refreshing the victim row and the other row can be performed at different times to avoid potential conflict on global input/output (GIO) lines. Refreshing a victim row during a refresh operation of another row allows for refreshing more victim rows during the same time period compared to past implementations that limited opportunities for refreshing victim rows.

A first implementation, which can be referred to as parallel usage-based disturbance mitigation during refresh pumps, refreshes at least one victim row while another row is refreshed as part of a normal refresh operation. A second implementation, which can be referred to as multi-wordline (WL) mitigation during usage-based disturbance mitigation refresh pumps, refreshes at least one additional victim row while another victim row is refreshed as part of a usage-based disturbance refresh operation. These implementations can be used individually or together.

### Example Operating Environments

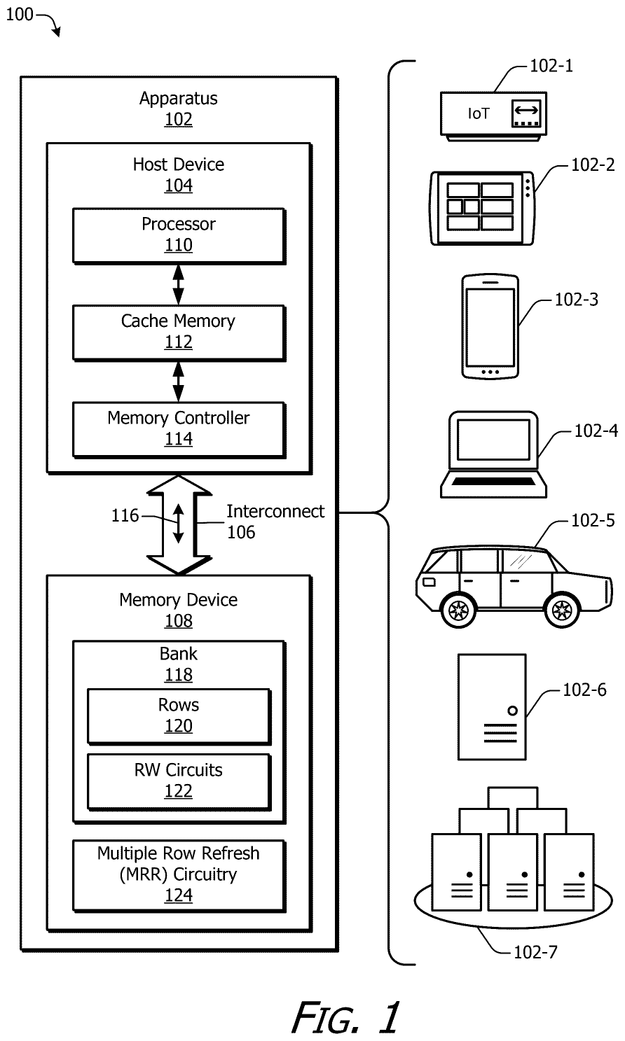

FIG. 1 illustrates, at 100 generally, an example operating environment including an apparatus 102 that can implement multiple-row refresh for usage-based disturbance mitigation. The apparatus 102 can include various types of electronic devices, including an internet-of-things (IoT) device 102-1, tablet device 102-2, smartphone 102-3, notebook computer 102-4, passenger vehicle 102-5, server computer 102-6, and server cluster 102-7 that may be part of cloud computing infrastructure, a data center, or a portion thereof (e.g., a PCB). Other examples of the apparatus 102 include a wearable device (e.g., a smartwatch or intelligent glasses), entertainment device (e.g., a set-top box, video dongle, smart television, a gaming device), desktop computer, motherboard, server blade, consumer appliance, vehicle, drone, industrial equipment, security device, sensor, or the electronic components thereof. Each type of apparatus can include one or more components to provide computing functionalities or features.

In example implementations, the apparatus 102 can include at least one host device 104, at least one interconnect 106, and at least one memory device 108. The host device 104 can include at least one processor 110, at least one cache memory 112, and a memory controller 114. The memory device 108, which can also be realized with a memory module, can include, for example, a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory for the apparatus 102. Although not illustrated, the apparatus 102 can also include storage memory. The storage memory can include, for example, a storage-class memory device (e.g., a flash memory, hard disk drive, solid-state drive, phase-change memory (PCM), or memory employing 3D XPoint™).

The processor 110 is operatively coupled to the cache memory 112, which is operatively coupled to the memory controller 114. The processor 110 is also coupled, directly or indirectly, to the memory controller 114. The host device 104 may include other components to form, for instance, a system-on-a-chip (SoC). The processor 110 may include a general-purpose processor, central processing unit, graphics processing unit (GPU), neural network engine or accelerator, application-specific integrated circuit (ASIC), field-programmable gate array (FPGA) integrated circuit (IC), or communications processor (e.g., a modem or baseband processor).

In operation, the memory controller 114 can provide a high-level or logical interface between the processor 110 and at least one memory (e.g., an external memory). The memory controller 114 may be realized with any of a variety of suitable memory controllers (e.g., a double-data-rate (DDR) memory controller that can process requests for data stored on the memory device 108). Although not shown, the host device 104 may include a physical interface (PHY) that transfers data between the memory controller 114 and the memory device 108 through the interconnect 106. For example, the physical interface may be an interface that is compatible with a DDR PHY Interface (DFI) group interface protocol. The memory controller 114 can, for example, receive memory requests from the processor 110 and provide the memory requests to external memory with appropriate formatting, timing, and reordering. The memory controller 114 can also forward to the processor 110 responses to the memory requests received from external memory.

The host device 104 is operatively coupled, via the interconnect 106, to the memory device 108. In some examples, the memory device 108 is connected to the host device 104 via the interconnect 106 with an intervening buffer or cache. The memory device 108 may operatively couple to storage memory (not shown). The host device 104 can also be coupled, directly or indirectly via the interconnect 106, to the memory device 108 and the storage memory. The interconnect 106 and other interconnects (not illustrated in FIG. 1) can transfer data between two or more components of the apparatus 102. Examples of the interconnect 106 include a bus (e.g., a unidirectional or bidirectional bus), switching fabric, or one or more wires that carry voltage or current signals. The interconnect 106 can propagate one or more communications 116 between the host device 104 and the memory device 108. For example, the host device 104 may transmit a memory request to the memory device 108 over the interconnect 106. Also, the memory device 108 may transmit a corresponding memory response to the host device 104 over the interconnect 106.

The illustrated components of the apparatus 102 represent an example architecture with a hierarchical memory system. A hierarchical memory system may include memories at different levels, with each level having memory with a different speed or capacity. As illustrated, the cache memory 112 logically couples the processor 110 to the memory device 108. In the illustrated implementation, the cache memory 112 is at a higher level than the memory device 108. A storage memory, in turn, can be at a lower level than the main memory (e.g., the memory device 108). Memory at lower hierarchical levels may have a decreased speed but increased capacity relative to memory at higher hierarchical levels.

The apparatus 102 can be implemented in various manners with more, fewer, or different components. For example, the host device 104 may include multiple cache memories (e.g., including multiple levels of cache memory) or no cache memory. In other implementations, the host device 104 may omit the processor 110 or the memory controller 114. A memory (e.g., the memory device 108) may have an “internal” or “local” cache memory. As another example, the apparatus 102 may include cache memory between the interconnect 106 and the memory device 108. Computer engineers can also include any of the illustrated components in distributed or shared memory systems.

Computer engineers may implement the host device 104 and the various memories in multiple manners. In some cases, the host device 104 and the memory device 108 can be disposed on, or physically supported by, a PCB (e.g., a rigid or flexible motherboard). The host device 104 and the memory device 108 may additionally be integrated together on an integrated circuit or fabricated on separate integrated circuits and packaged together. The memory device 108 may also be coupled to multiple host devices 104 via one or more interconnects 106 and may respond to memory requests from two or more host devices 104. Each host device 104 may include a respective memory controller 114, or the multiple host devices 104 may share a memory controller 114. This document describes with reference to FIG. 1 an example computing system architecture having at least one host device 104 coupled to a memory device 108.

Two or more memory components (e.g., modules, dies, banks, or bank groups) can share the electrical paths or couplings of the interconnect 106. The interconnect 106 can include at least one command-and-address bus (CA bus) and at least one data bus (DQ bus). The command-and-address bus can transmit addresses and commands from the memory controller 114 of the host device 104 to the memory device 108, which may exclude propagation of data. The data bus can propagate data between the memory controller 114 and the memory device 108. The memory device 108 may also be implemented as any suitable memory including, but not limited to, DRAM, SDRAM, three-dimensional (3D) stacked DRAM, DDR memory, or LPDDR memory (e.g., LPDDR DRAM or LPDDR SDRAM).

The memory device 108 can form at least part of the main memory of the apparatus 102. The memory device 108 may, however, form at least part of a cache memory, a storage memory, or a system-on-chip of the apparatus 102. The memory device 108 includes at least one memory bank 118. The bank 118 includes rows 120 and read-write (RW) circuits 122 (RW circuits 122). Memory cells within the rows 120 can be subjected to usage-based disturbance generated by the unintentional or intentional repeated activation of neighboring rows within the rows 120.

A read-write circuit 122 enables the memory device 108 to perform a read operation and/or a write operation. Each of the read-write circuits 122 can include one or more first components that support the read operation, one or more second components that support the write operation, one or more third components that support both the read operation and the write operation, or some combination thereof. Example components of the read-write circuits 122 can include digit lines and sense amplifiers (e.g., a sense amplifier circuit or an array of sense amplifiers).

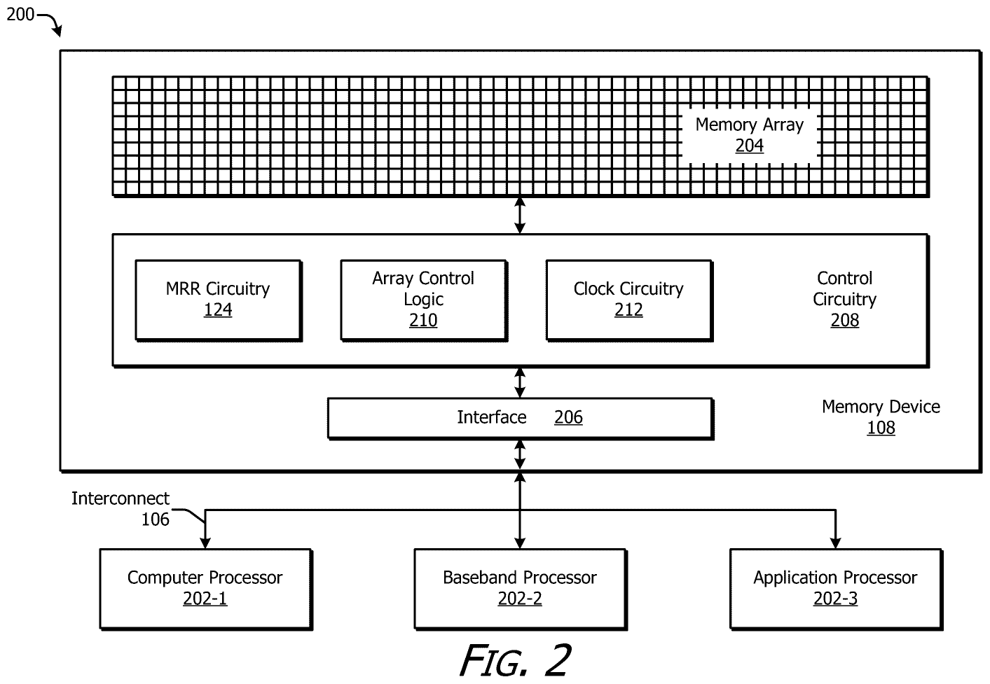

The memory device 108 also includes multiple-row refresh (MRR) circuitry 124. The multiple-row refresh circuitry 124 mitigates usage-based disturbance by refreshing at least one victim row for usage-based disturbance mitigation during a refresh operation that involves another row of the rows 120. The victim row is an additional row that is effectively refreshed in parallel with the other row. Additional rows that can be refreshed are coupled to components that are not shared by the other row associated with the refresh operation. For example, the victim row and the other row can be coupled to different read-write circuits 122. Refreshing a victim row during a refresh operation of another row allows for refreshing more victim rows during the same time period compared to past implementations that limited opportunities for refreshing victim rows. The multiple-row refresh circuitry 124 is further described with respect to FIG. 2.

FIG. 2 illustrates an example computing system 200 that can implement aspects of multiple-row refresh for usage-based disturbance mitigation. In some implementations, the computing system 200 includes at least one memory device 108, at least one interconnect 106, and at least one processor 202. The memory device 108 can include, or be associated with, at least one memory array 204, at least one interface 206, and control circuitry 208 (or periphery circuitry) operatively coupled to the memory array 204. The memory array 204 can include an array of memory cells, including but not limited to memory cells of DRAM, SDRAM, three-dimensional (3D) stacked DRAM, DDR memory, LPDDR SDRAM, and so forth. The memory array 204 and the control circuitry 208 may be components on a single semiconductor die or on separate semiconductor dies. The memory array 204 or the control circuitry 208 may also be distributed across multiple dies. This control circuitry 208 may manage traffic on a bus that is separate from the interconnect 106.

The control circuitry 208 can include various components that the memory device 108 can use to perform various operations. These operations can include communicating with other devices, managing memory performance, performing refresh operations (e.g., self-refresh operations or auto-refresh operations), and performing memory read or write operations. For example, the control circuitry 208 can include at least one instance of array control logic 210 and clock circuitry 212. The array control logic 210 can include circuitry that provides command decoding, address decoding, input/output functions, amplification circuitry, power supply management, power control modes, and other functions. The clock circuitry 212 can synchronize various memory components with one or more external clock signals provided over the interconnect 106, including a command-and-address clock or a data clock. The clock circuitry 212 can also use an internal clock signal to synchronize memory components and may provide timer functionality.

The control circuitry 208 also includes the multiple-row refresh circuitry 124. In general, the multiple-row refresh circuitry 124 is coupled to the memory array 204 and refreshes at least one usage-based disturbance victim row in a bank of the memory array 204 while refreshing another row in the same bank. The multiple-row refresh circuitry 124 can also be coupled to other components within the control circuitry 208 to operate with the other components to refresh a victim row in addition to other rows that have already been scheduled for refreshing.

The interface 206 can couple the control circuitry 208 or the memory array 204 directly or indirectly to the interconnect 106. In some implementations, the multiple-row refresh circuitry 124, the array control logic 210, and the clock circuitry 212 can be part of a single component (e.g., the control circuitry 208). In other implementations, one or more of the multiple-row refresh circuitry 124, the array control logic 210, or the clock circuitry 212 may be implemented as separate components, which can be provided on a single semiconductor die or disposed across multiple semiconductor dies. These components may individually or jointly couple to the interconnect 106 via the interface 206.

The interconnect 106 may use one or more of a variety of interconnects that communicatively couple together various components and enable commands, addresses, or other information and data to be transferred between two or more components (e.g., between the memory device 108 and the processor 202). Although the interconnect 106 is illustrated with a single line in FIG. 2, the interconnect 106 may include at least one bus, at least one switching fabric, one or more wires or traces that carry voltage or current signals, at least one switch, one or more buffers, and so forth. Further, the interconnect 106 may be separated into at least a command-and-address bus and a data bus.

In some aspects, the memory device 108 may be a “separate” component relative to the host device 104 (of FIG. 1) or any of the processors 202. The separate components can include a PCB, memory card, memory stick, and memory module (e.g., a single in-line memory module (SIMM) or dual in-line memory module (DIMM)). Thus, separate physical components may be located together within the same housing of an electronic device or may be distributed over a server rack, a data center, and so forth. Alternatively, the memory device 108 may be integrated with other physical components, including the host device 104 or the processor 202, by being combined on a PCB or in a single package or a system-on-chip.

As shown in FIG. 2, the processors 202 may include a computer processor 202-1, a baseband processor 202-2, and an application processor 202-3, coupled to the memory device 108 through the interconnect 106. The processors 202 may include or form a part of a central processing unit, graphics processing unit, system-on-chip, application-specific integrated circuit, or field-programmable gate array. In some cases, a single processor can comprise multiple processing resources, each dedicated to different functions (e.g., modem management, applications, graphics, central processing). In some implementations, the baseband processor 202-2 may include or be coupled to a modem (not illustrated in FIG. 2) and referred to as a modem processor. The modem or the baseband processor 202-2 may be coupled wirelessly to a network via, for example, cellular, Wi-Fi®, Bluetooth®, near field, or another technology or protocol for wireless communication.

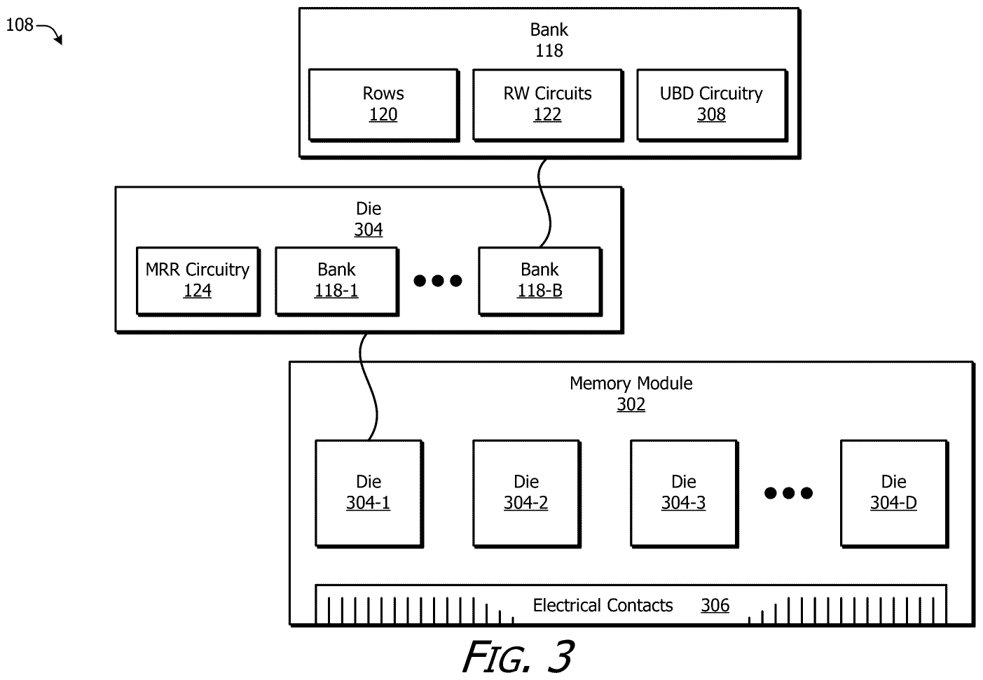

In some implementations, the processors 202 may be connected directly to the memory device 108 (e.g., via the interconnect 106). In other implementations, one or more of the processors 202 may be indirectly connected to the memory device 108 (e.g., over a network connection or through one or more other devices). The multiple-row refresh circuitry 124 is further described with respect to FIG. 3.

### Example Techniques and Hardware

FIG. 3 illustrates an example memory device 108 in which aspects of multiple-row refresh for usage-based disturbance mitigation can be implemented. The memory device 108 includes a memory module 302, which can include multiple dies 304. As illustrated, the memory module 302 includes a first die 304-1, a second die 304-2, a third die 304-3, and a Dth die 304-D, with D representing a positive integer. The memory module 302 can be a SIMM or a DIMM. As another example, the memory module 302 can interface with other components via a bus interconnect (e.g., a Peripheral Component Interconnect Express (PCIe®) bus). The memory device 108 illustrated in FIGS. 1 and 2 can correspond, for example, to multiple dies (or dice) 304-1 through 304-D, or a memory module 302 with two or more dies 304. As shown, the memory module 302 can include one or more electrical contacts 306 (e.g., pins) to interface the memory module 302 to other components.

The memory module 302 can be implemented in various manners. For example, the memory module 302 may include a PCB, and the multiple dies 304-1 through 304-D may be mounted or otherwise attached to the PCB. The dies 304 (e.g., memory dies) may be arranged in a line or along two or more dimensions (e.g., forming a grid or array). The dies 304 may have a similar size or may have different sizes. Each die 304 may be similar to another die 304 or different in size, shape, data capacity, or control circuitries. The dies 304 may also be positioned on a single side or on multiple sides of the memory module 302.

One or more of the dies 304-1 to 304-D can include banks 118-1 to 118-B, with B representing a positive integer. One or more of the banks 118 can include rows 120, read-write circuits 122, and the multiple-row refresh circuitry 124. In different examples, the multiple-row refresh circuitry 124 can be local bank circuitry on the bank 118, can be central circuitry on the die 304, can include some circuitry on the bank 118 and some circuitry on the die 304, and/or can otherwise be single and/or a combination of distributed circuitry on the memory module 302. In this example, multiple-row refresh circuitry 124 on the die 304 decides whether an additional refresh operation can be performed based on a victim row in the bank 118 not being coupled to the same read-write circuit 122 as another row that is scheduled to be refreshed in the same bank 118. The multiple-row refresh circuitry 124 can refresh the victim row while refreshing the other row if they are not coupled to the same read-write circuit 122.

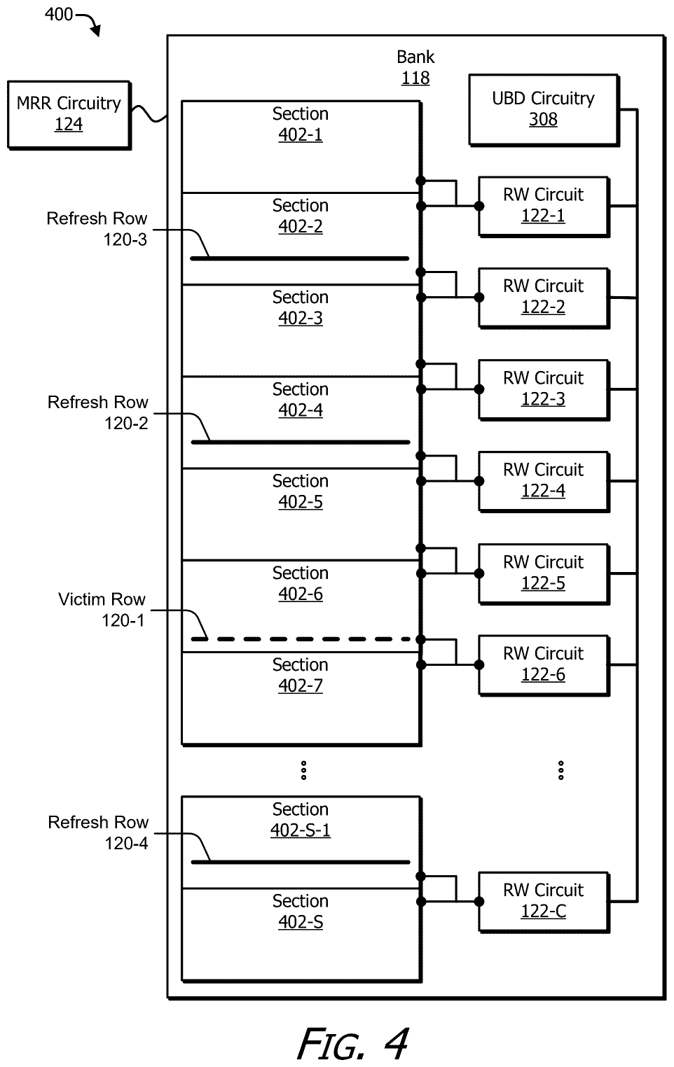

The bank 118 can also include usage-based disturbance (UBD) circuitry 308. The usage-based disturbance circuitry 308 can also be located on one or more of the dies 304-1 through 304-D, can be distributed between the dies 304-1 through 304-D and the bank 118, and/or can be located elsewhere on the memory module 302. In general, the usage-based disturbance circuitry 308 monitors conditions associated with, and performs operations to mitigate, usage-based disturbance. The usage-based disturbance circuitry 308 can operate in conjunction with the multiple-row refresh circuitry 124 to allow the multiple-row refresh circuitry 124 to further mitigate usage-based disturbance. For example, the usage-based disturbance circuitry 308 issues commands and/or provides information to the multiple-row refresh circuitry 124, which the multiple-row refresh circuitry 124 uses to perform an additional refresh operation of at least one victim row. The relationship between the rows 120, the read-write circuits 122, and the multiple-row refresh circuitry 124 are further described with respect to FIG. 4.

FIG. 4 illustrates an example bank 118 in which aspects of multiple-row refresh for usage-based disturbance mitigation can be implemented according to a first implementation 400. The first implementation 400 can be referred to as a parallel usage-based disturbance mitigation during refresh pumps implementation that refreshes at least one victim row while at least one other row is refreshed as part of a normal refresh operation. The bank 118 can be coupled to and/or can include the multiple-row refresh circuitry 124. The bank 118 can also include the read-write circuits 122-1 through 122-C, where C represents a positive integer. Rows of memory cells in the bank 118 are divided into sections 402-1 through 402-S, where S represents a positive integer. Groups of the sections 402 can share read-write circuits 122. For example, sections 402-3 and 402-4 (or at least portions of sections 402-3 and 402-4) can share read-write circuit 122-3.

In FIG. 4, the usage-based disturbance circuitry 308 is shown to be implemented at a local-bank level and considered part of the bank 118. In this case, different instances of the usage-based disturbance circuitry 308 can mitigate usage-based disturbance for different banks 118 or different sets of banks 118. Other implementations, however, are also possible in which the usage-based disturbance circuitry 308 are implemented at the global level (or center level) and coupled to the bank 118. At the global level, the usage-based disturbance circuitry 308 can mitigate usage-based disturbance for multiple banks 118, including the bank 118 shown in FIG. 4. In other implementations, portions of the usage-based disturbance circuitry 308 are at the global level and portions are at the local-bank level.

Row 120-1 represents a usage-based disturbance victim row and rows 120-2 through 120-4 represent rows that are being refreshed during a normal refresh operation. The normal refresh operation can be a scheduled refresh operation, a periodic refresh operation, a scheduled or triggered usage-based disturbance mitigation refresh operation, or another scheduled or triggered refresh operation.

In operation, the multiple-row refresh circuitry 124 can refresh the victim row 120-1 of the bank 118 while refreshing the normally refreshed row 120-2 in the same bank 118. The refresh of the victim row 120-1 can be considered an opportunistic refresh, a piggyback refresh, or an extra/additional refresh along with the normally refreshed row 120-2. The victim row 120-1 can be refreshed while refreshing the normally refreshed row 120-2, but the refresh operation may not start at the same time. For example, the refresh operations may be simultaneous, such as parallel, in that the refresh operations overlap at some point in time. Other normally refreshed rows including at least rows 120-3 and 120-4 can also be refreshed while refreshing the victim row 120-1 and the normally refreshed row 120-2.

The victim row 120-1 can be an additional/extra row that can be refreshed if a non-shared read circuit condition is satisfied. If the condition is not satisfied, the victim row 120-1 may not be refreshed and the normally refreshed row 120-2 can still be refreshed. In particular, the victim row 120-1 and the normally refreshed row 120-2 should not share a digit line, sense amplifier, or other components related to a read-write circuit 122 if they are concurrently refreshed. Otherwise, the sharing of components related to a read-write circuit 122 may cause data corruption in the memory cells of the corresponding rows.

The multiple-row refresh circuitry 124 can determine whether the victim row 120-1 is coupled to a different read-write circuit 122 than the normally refreshed row 120-2 to avoid the victim row 120-1 sharing the same read-write circuit 122 as the normally refreshed row 120-2 when the rows 120-1 and 120-2 are concurrently refreshed. In a first example implementation, the multiple-row refresh circuitry 124 determines that the victim row 120-1 and the normally refreshed row 120-2 are coupled to different read-write circuits 122 based on location information associated with these rows (e.g., based on their position within the bank 118). This location information can include the sections 402 corresponding to these rows, sides of the memory array 204 that correspond to these rows, or some combination thereof. Relying on the location information to determine the non-shared read circuit condition can reduce a complexity of the multiple-row refresh circuitry 124.

In a second example implementation, the multiple-row refresh circuitry 124 directly identifies the read-write circuits 122 that are coupled to the victim row 120-1 and the normally refreshed row 120-2. The multiple-row refresh circuitry 124, for instance, can reference a table of information that associates each row address with a particular read-write circuit. Although this may increase a complexity of the multiple-row refresh circuitry 124, it can enable more victim rows to be refreshed compared to the first example implementation.

Consider an example in which a victim row is present in a same section as the refresh row 120-2 or is present in a neighboring section relative to the refresh row 120-2. With this second example implementation, the multiple-row refresh circuitry 124 can determine that the victim row is coupled to the read-write circuits 122-4 or 122-5 and determine that the refresh row 120-2 is coupled to the read-write circuit 122-3. As such, the non-shared read-write circuit condition is satisfied and the victim row can be refreshed along with the refresh row 120-2 even though the victim row and the refresh row 120-2 are in the same section or neighboring sections.

In the present case, the victim row 120-1 is coupled to read-write circuits 122-5 and/or 122-6, which are different than the read-write circuits 122-3 and/or 122-4 coupled to the normally refreshed row 120-2. Thus, the condition is satisfied and the multiple-row refresh circuitry 124 can refresh the victim row 120-1 while refreshing the normally refreshed row 120-2. If the multiple-row refresh circuitry 124 determines the victim row 120-1 is coupled to the same read-write circuit 122 as the normally refreshed row 120-2, then the multiple-row refresh circuitry 124 will abstain from refreshing the victim row 120-1 while refreshing the normally refreshed row 120-2. The victim row 120-1 should also be coupled to different read-write circuits 122 than the other refresh rows 120-3 and 120-4 if the corresponding refresh operations would overlap in time.

Rows of memory cells in the sections 402 can be word lines that share at least one read-write circuit 122. As shown, the victim row 120-1 is in a section 402-6 of the bank 118 that is coupled to read-write circuits 122-5 and 122-6. The normally refreshed row 120-2 is in a section 402-4 that is coupled to read-write circuits 122-3 and 122-4. Separate read-write circuits 122 can be different from each other in that they have components that are distinct/separate/electrically decoupled/not associated with each other. The read-write circuits 122 can otherwise be similar circuits in that they can have similar types of components and/or a similar quantity of these components.

In a first possible embodiment, the multiple-row refresh circuitry 124 determines whether the victim row 120-1 is coupled to the same read-write circuit 122 as the normally refreshed row 120-2 by determining whether the victim row 120-1 is in the same section as, or a neighboring section that is immediately adjacent to, the normally refreshed row 120-2. In particular, if the victim row 120-1 and the normally refreshed row 120-2 are in different and non-neighboring sections, they will not share a digit line, sense amplifier, and/or other component of a read-write circuit 122 and can be concurrently refreshed. In the present case, another section 402-5 is located between sections 402-6 and 402-4 that respectively contain the victim row 120-1 and the normally refreshed row 120-2. Thus, the multiple-row refresh circuitry 124 can determine that sections 402-6 and 402-4 are not immediately adjacent, that the respective victim row 120-1 and normally refreshed row 120-2 thus do not share read-write circuits 122, and that refresh operations can be performed simultaneously on the victim row 120-1 and the normally refreshed row 120-2.

For example, the victim row 120-1 that needs to be refreshed for usage-based disturbance mitigation is in a different, non-neighboring section 402-6 from the section 402-4 of the normally refreshed row 120-2, as well as the sections including other normally refreshed rows 120-3 and 120-4, which allows for an extra refresh operation of the victim row 120-1. If the only victim rows that need to be refreshed for usage-based disturbance mitigation is in a section that shares read-write circuitry with any of the normally refreshed rows 120-2 through 120-4, the multiple-row refresh circuitry 124 may not perform extra refresh operations that overlap with refresh operations of the normally refreshed rows 120-2 through 120-4.

In a second possible embodiment, the memory device 108 represents a large density device having a memory array 204 with multiple sides (e.g., a P-side and a Q-side). In this case, the multiple-row refresh circuitry 124 determines whether the victim row 120-1 is coupled to the same read-write circuit 122 as the normally refreshed row 120-2 by determining whether the victim row 120-1 is on a same side of the of the memory array 204 compared to the normally refreshed row 120-2. In particular, if the victim row 120-1 and the normally refreshed row 120-2 are on different sides of the memory array 204, they will not share a digit line, sense amplifier, and/or other component of a read-write circuit 122 and can be concurrently refreshed. Consider a case in which the victim row 120-1 and the normally refreshed row 120-2 are on different sides of the memory array 204 (e.g., the victim row 120-1 is on the P-side and the normally refreshed row 120-2 is on the Q-side, or vice versa). In this case, the multiple-row refresh circuitry 124 can determine that refresh operations can be performed simultaneously on the victim row 120-1 and the normally refreshed row 120-2.

In a possible implementation, the usage-based disturbance circuitry 308 identifies at least one victim row that is to be refreshed to mitigate usage-based disturbance within the bank 118. The multiple-row refresh circuitry 124 determines the identified victim row is coupled to a read-write circuit 122 different from the normally refreshed row 120-2 based on determining that an address of the identified victim row is in a different and non-neighboring section of the bank 118 than the normally refreshed row 120-2. In response to determining the identified victim row is coupled to a read-write circuit 122 different than the victim row 120-1, the multiple-row refresh circuitry 124 refreshes the victim row 120-1 as the identified victim row.

For example, the usage-based disturbance circuitry 308 can determine the victim row 120-1 is in a different section 402 of the bank 118 than the normally refreshed row 120-2 based on an address of the victim row 120-1 indicating it is a victim row in a different section 402 from the normally refreshed row 120-2, based on an address of an aggressor row proximal to the victim row 120-1 being in a different section from the normally refreshed row 120-2, and/or based on other information.

In a possible example, the usage-based disturbance circuitry 308 determines a usage-based disturbance operation is needed for the victim row 120-1 by detecting an aggressor row (not shown) in the same section as the victim row 120-1. The victim row 120-1 can be a victim row in that it is affected by multiple activations of the aggressor row. The aggressor row can be a neighboring row of the victim row 120-1 in that can be can be an immediately adjacent row or a row in close enough proximity to the victim row 120-1 to cause usage-based disturbance of the victim row 120-1.

The usage-based disturbance circuitry 308 can provide victim row information regarding a particular victim row or list of victim rows to the multiple-row refresh circuitry 124. The multiple-row refresh circuitry 124, can process the victim row information to determine whether the victim row 120-1 is coupled to different read-write circuitry than the normally refreshed row 120-2. In a possible embodiment, the victim row information can include aggressor row information that allows the multiple-row refresh circuitry 124 to identify victim rows that are proximal to aggressor rows. For example, the usage-based disturbance circuitry 308 places information about an aggressor row in a queue of aggressor rows. The multiple-row refresh circuitry 124 can access the queue and identify the victim row(s) based on proximity to an aggressor row in the queue. The identified victim rows can be within +/−1 rows, +/−2 rows, or otherwise determined to be proximal to the aggressor row.

Refresh circuitry that activates/performs the refresh of the victim row 120-1 and normally refreshed row 120-2 can be part of the same circuitry or can be separate circuitry from the usage-based disturbance circuitry 308 and/or the multiple-row refresh circuitry 124. The refresh circuitry can also be the same or different circuitry for each of the victim row 120-1 and the normally refreshed row 120-2.

In a possible embodiment, the multiple-row refresh circuitry 124 receives a command that allows for a quantity of refresh operations to be performed in series within the bank 118. The command can be provided by the usage-based disturbance circuitry 308 or other circuitry external to the bank 118. The command can be a usage-based disturbance mitigation command, can be a refresh management (RFM) command, can be or can be related to a self-refresh command, can be or can be related to an auto-refresh command, can be a normal refresh command, and/or can be any other command relating to refreshing at least one row in the bank 118. In a possible example, the command can be a high-level command. For example, central logic circuitry can communicate the command to local bank logic, such as to the usage-based disturbance circuitry 308 and/or the multiple-row refresh circuitry 124, to indicate that it has time to perform a specified number of refresh operations/pumps in a series/sequential manner. The local bank logic performs these refresh operations and can perform at least one additional refresh operation in parallel to mitigate usage-based disturbance.

The multiple-row refresh circuitry 124 performs the quantity of refresh operations by at least refreshing the normally refreshed row 120-2. The multiple-row refresh circuitry 124 also performs at least one additional refresh operation by at least refreshing the victim row 120-1 during a time interval in which the circuitry performs the quantity of refresh operations.

In a possible implementation, each row in the bank 118 is configured to store data associated with usage-based disturbance within a subset of the memory cells of the corresponding row. For example, to monitor for usage-based disturbance, an activation count can be stored within each row of the bank 118. The activation count keeps track of a quantity of accesses or activations of the corresponding memory row and can be updated using an activation count update (ACU) operation. If the activation count meets or exceeds a threshold, proximate rows, including one or more adjacent rows, may be victim rows with increased risk for data corruption due to the repeated activations of the accessed row and the usage-based disturbance effect. To manage this risk to the affected rows, the usage-based disturbance circuitry 308 and/or the multiple-row refresh circuitry 124 can refresh the proximate rows.

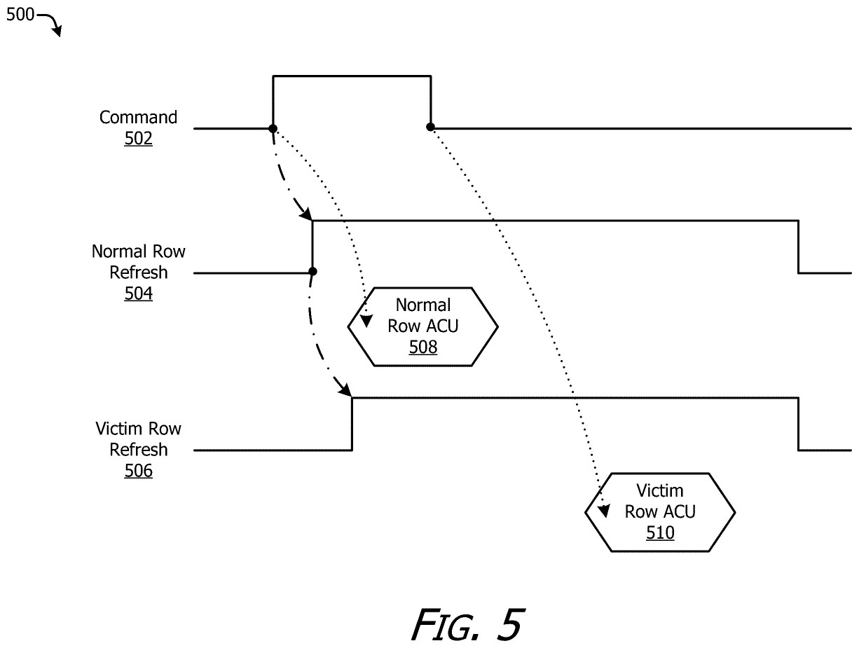

Upon refreshing the victim row 120-1, the multiple-row refresh circuitry 124 updates data associated with usage-based disturbance of the victim row 120-1 at a different time than updating data associated with usage-based disturbance of the normally refreshed row 120-2. For example, the multiple-row refresh circuitry 124 updates the data associated with usage-based disturbance by performing the ACU operation. As mentioned above, the data associated with usage-based disturbance can include an activation count that represents a number, such as a quantity, of times a corresponding row has been accessed since a last refresh. The activation count of each row can be updated at different times to avoid conflicts, such as a conflict on shared GIO data lines or other conflicts. The timing of updating the data is further described with respect to FIG. 5.

FIG. 5 illustrates an example timing diagram 500 of a memory device 108 implementing one or more aspects of multiple-row refresh for usage-based disturbance mitigation. After a command 502 is received, a normal row can be refreshed 504 and a victim row can be refreshed 506 simultaneously with refreshing of the normal row 504. The command 502 can be a usage-based disturbance mitigation command, a refresh management command, a self-refresh command, an auto-refresh command, a normal refresh command, and/or can be any other command relating to refreshing at least one row in the bank 118. To avoid conflict of data, the data associated with usage-based disturbance of the victim row is updated 508, such as using an ACU operation, at a different time than the data associated with usage-based disturbance of the normally refreshed row is updated 510. Data associated with usage-based disturbance can be updated by resetting a counter to a particular value, by clearing a counter to zero, by adding or subtracting a determined or set value to or from a stored value, or by otherwise updating data to reflect user-based disturbance mitigation operations.

In a possible example, a normal row refresh ACU operation 508 is performed at a different time than the victim row refresh ACU operation 510. Different triggers can cause the normal row refresh ACU operation 508 and the victim row refresh ACU operation 510 to be performed at different times. For example, the normal row refresh ACU operation 508 is triggered by the command 502, and the victim row refresh ACU operation 510 is triggered by the falling edge of the command 502, by the end of the normal row refresh ACU operation 508, by the victim row refresh operation 506, or by any other command or signal that occurs after a signal or command that triggers the normal row refresh ACU operation 508. In another example, a delay period can be set to perform the ACU operations 508 and 510 at different times, such that the normal row ACU refresh operation 508 does not overlap with the victim row ACU operation 510.

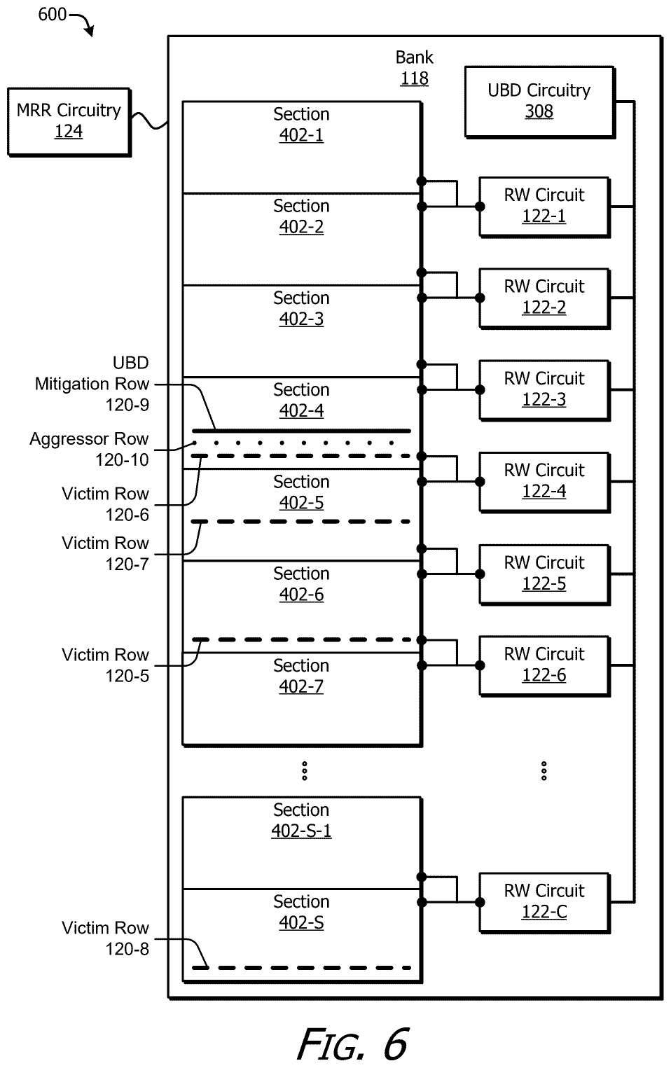

In FIGS. 4 and 5, the multi-row refresh circuitry 124 is shown to enable one victim row to be refreshed along with a normal refresh row. Other implementations are also possible in which the multi-row refresh circuitry 124 enables more than one victim row (e.g., two, three, four, or ten victim rows) to be refreshed along with a normal refresh row. In general, any quantity of victim rows can be refreshed along with a normal refresh row so long as the additional victim rows satisfy the non-shared read-write circuit condition and the refreshing of the additional victim rows can be performed within available power constraints of the memory device 108 and can be performed within a timing constraint associated with the refreshing of the normal refresh row. Another example implementation of multiple-row refresh for usage-based disturbance mitigation is described with respect to FIG. 6.

FIG. 6 illustrates an example bank 118 in which aspects of multiple-row refresh for usage-based disturbance mitigation can be implemented according to a second implementation 600. The second implementation 600 can be referred to as a multi-WL mitigation during usage-based disturbance mitigation refresh pumps implementation. The second implementation can include all the features of the first implementation 400 of FIG. 4, except that it refreshes at least one additional victim row while another victim row is refreshed as part of a usage-based disturbance refresh operation. The first implementation 400 and the second implementation 600 can be used individually or together.

In the second implementation 600 of FIG. 6, the bank 118 can be coupled to and/or can include the multiple-row refresh circuitry 124. The bank 118 can also include the read-write circuits 122-1 through 122-C. Rows of cells in the bank 118 are divided into sections 402-1 through 402-S. Groups of sections 402 can share read-write circuits 122. For example, sections 402-3 and 402-4 can share read-write circuit 122-3. The usage-based disturbance circuitry 308 can be coupled to and/or can be included within the bank 118.

Rows 120-5 through 120-9 represent usage-based disturbance victim rows, where rows 120-5 through 120-8 represent victim rows that have not yet been scheduled for usage-based disturbance mitigation. Row 120-9 represents a victim row that is scheduled for usage-based disturbance mitigation. For example, a targeted/dedicated refresh command can be received that allocates a targeted/dedicated usage-based disturbance mitigation pump to row 120-9.

The multiple-row refresh circuitry 124 refreshes at least one victim row 120, such as victim row 120-5 while refreshing the usage-based disturbance mitigation row 120-9 when the victim row 120-5 does not share a read-write circuit 122 with the usage-based disturbance mitigation row 120-9. The multiple-row refresh circuitry 124 of FIG. 6 can have similar logic or perform similar operations as described with respect to the multiple-row refresh circuitry 124 of FIG. 4 to determine whether or not the non-shared read-write circuit condition is satisfied.

The multiple-row refresh circuitry 124 refreshes the victim row 120-5 while refreshing the usage-based disturbance mitigation row 120-9 in response to receiving a targeted refresh command to refresh the usage-based disturbance mitigation row 120-9. The targeted refresh command can be usage-based disturbance mitigation command that targets row 120-9 as a victim row, that targets multiple rows as victim rows, that identifies an aggressor row for determination of victim rows, or that otherwise targets a particular row or multiple rows for usage-based disturbance mitigation. Other conditions can trigger refreshing the usage-based disturbance mitigation row 120-9 and/or refreshing the victim row 120-5. Such conditions can include the existence of a dedicated usage-based disturbance mitigation pump, receiving an RFM command, or other conditions.

As discussed above, the refresh of the victim row 120-5 can be considered an opportunistic refresh, a piggyback refresh, or an extra/additional refresh along with the refresh of the usage-based disturbance mitigation row 120-9. The victim row 120-5 can be refreshed while refreshing the usage-based disturbance mitigation row 120-9, but the refresh operation may not start at the exact same time. For example, the refresh operations may be simultaneous, such as parallel, in that the refresh operations overlap at some point in time.

To elaborate on a possible example, row 120-10 represents an aggressor row that can cause usage-based disturbance of proximal victim rows 120-6 and 120-9. A determination can be made by usage-based disturbance circuitry 308 or other external circuitry that the aggressor row 120-10 has been accessed frequently, such as repeatedly within a time threshold, which may cause data corruption to victim rows that are proximate to the aggressor row 120-10. The frequent access of the aggressor row 120-10 row can be identified by using a counter that stores how often the row 120-10 is accessed and by determining the value of the counter exceeds a threshold number of accesses in a certain period, such as in between periodic refreshes of the row 120-10. The usage-based disturbance circuitry 308 or other circuitry can determine row 120-9 is a victim row and issue a targeted refresh command to refresh the second row. A usage-based disturbance mitigation refresh pump can be allocated to mitigate usage-based disturbance of row 120-9.

There also may be other victim rows 120-6 through 120-8 that could benefit from usage-based disturbance mitigation. Information about aggressor rows that cause usage-based disturbance of victim rows can be stored in a queue and the multiple-row refresh circuitry 124 can determine the victim rows 120-5 through 120-8 based on the aggressor row information. As discussed above, the multiple-row refresh circuitry 124 may only refresh victim rows that satisfy certain criteria, such as by not being coupled to a read-write circuit of another row that is currently being refreshed. For example, victim row 120-6 may not be refreshed while usage-based disturbance mitigation row 120-9 is refreshed because they share at least one read circuit, such as read-write circuits 122-3 and/or 122-4. Victim row 120-7 also may not be refreshed while usage-based disturbance mitigation row 120-9 is refreshed because they are in neighboring sections 402-4 and 402-5 that share read-write circuit 122-4. However, victim rows 120-5 and 120-8 may be refreshed while usage-based disturbance mitigation row 120-9 is refreshed because they do not share a read-write circuit 122 with usage-based disturbance mitigation row 120-9.

The multiple-row refresh circuitry 124 can determine the victim row 120-5 is coupled to a different read-write circuit than the usage-based disturbance mitigation row 120-9. Thus, the condition is satisfied and the multiple-row refresh circuitry 124 will refresh the victim row 120-5 while refreshing the usage-based disturbance mitigation row 120-9. The multiple-row refresh circuitry 124 may also refresh an extra victim row 120-8 while refreshing rows 120-5 and 120-9 because victim row 120-8 is coupled to a read-write circuit 122-C that is different from read-write circuits coupled to concurrently refreshed rows 120-5 and 120-9. As noted, there are other victim rows 120-6 and 120-7 that are coupled to the same read-write circuit 122-4 as the usage-based disturbance mitigation row 120-9. Thus, the multiple-row refresh circuitry 124 will abstain from refreshing the victim rows 120-6 and 120-7 while refreshing the usage-based disturbance mitigation row 120-9 because they are coupled to the same read-write circuit 122-4 as the usage-based disturbance mitigation row 120-9.

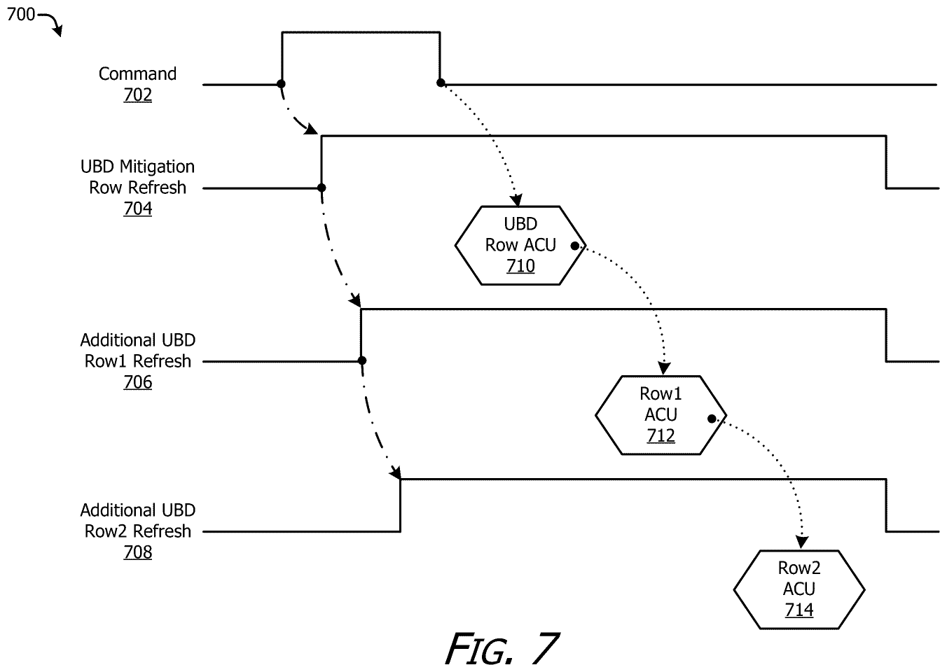

Upon concurrently refreshing the victim rows 120-9, 120-5, and/or 120-8, the multiple-row refresh circuitry 124 updates data associated with usage-based disturbance of the respective refreshed victim rows at different times. For example, the multiple-row refresh circuitry 124 updates the data associated with usage-based disturbance by performing an ACU operation for each refreshed row at different times. As mentioned above, the data associated with usage-based disturbance can include an activation count that represents a number, such as a quantity, of times a corresponding row has been accessed since a last refresh. The activation count can be stored within the corresponding rows or otherwise stored in memory. The timing of updating the usage-based disturbance data is further described with respect to FIG. 7.

FIG. 7 illustrates an example timing diagram 700 of a memory device 108 implementing one or more aspects of multiple-row refresh for usage-based disturbance mitigation. After a command 702 is received, a usage-based disturbance mitigation row can be refreshed 704 and at least one additional usage-based disturbance victim row can be refreshed 706 and/or 708. The command 702 can be similar to the command 502. The usage-based-disturbance mitigation row and the one or more additional usage-based-disturbance victim rows are coupled to different read-write circuits 122. This can mean that the usage-based-disturbance mitigation row and the one or more additional usage-based-disturbance victim rows are associated with different sections 402 of the bank 118 in some instances. The usage-based-disturbance mitigation row and the one or more additional usage-based-disturbance victim rows can be victims of aggressor rows that are in different sections 402 of the bank 118. For example, the usage-based-disturbance mitigation row can be a victim of a first aggressor row that is in a first section 408. The additional usage-based-disturbance victim row can be a victim of a second aggressor row that is in a second section 408. Another usage-based-disturbance victim row can be a victim of a third aggressor row that is in a third section 408.

As the usage-based-disturbance mitigation row and the one or more additional usage-based-disturbance victim rows do not share a read-write circuit 122, multi-WL mitigation can be performed to refresh these rows during a same time period. In this manner, the techniques for performing multi-WL mitigation provides usage-based disturbance mitigation for more than one row at a time, thereby improving an efficiency of the memory device 108 with respect to mitigating usage-based disturbance.

To avoid conflict of data, the data associated with usage-based disturbance for the refreshed rows is updated 710, 712, and 714 at different times by the usage-based-disturbance circuitry 308, such as by using an ACU operation. For example, read-write circuits 122 in a bank 118 may share the same ACU circuit and each operation of the ACU circuit that updates the data of each corresponding row may not overlap in time. Data associated with usage-based disturbance can be updated by resetting a counter to a particular value, by clearing a counter to zero, by adding or subtracting a determined or set value to a stored value, or by otherwise updating data to reflect user-based disturbance mitigation operations. Different triggers can cause the ACU operations 710, 712, and 714 to be performed at different times. For example, the ACU operations can be triggered by various commands that occur at different times, by different edges of different signals, by determined or preset delay periods, or by other triggers or operations.

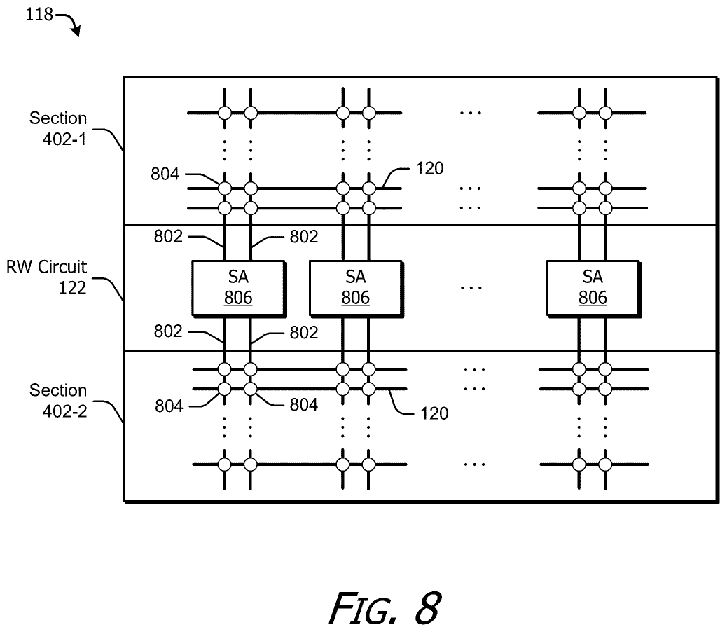

FIG. 8 illustrates an example relationship between a read-write circuit 122 and sections 402 of the bank 118. Sections 402 of the bank 118, such as sections 402-1 and 402-2, can be physically divided by the read-write circuit 122 while still being adjacent. The read-write circuit 122 includes a set of digit lines 802 coupled to sets of memory cells 804 in a first section 402-1. The read-write circuit 122 also includes a set of sense amplifiers (SA) 806 coupled to the sets of digit lines 802 and configured to read data on the digit lines 802 from the set of memory cells 804 within the first section 402-1. The sense amplifiers 806 are also coupled to digit lines 802 that are coupled to memory cells 804 in the second section 402-2. The sense amplifiers 806 in the read-write circuit 122 can be used for both read operations and write operations. The rows 120 in sections 402-1 and 402-2 may not be refreshed in parallel because they are coupled to the same digit lines 802 and sense amplifiers 806 in the same read-write circuit 122.

### Example Method

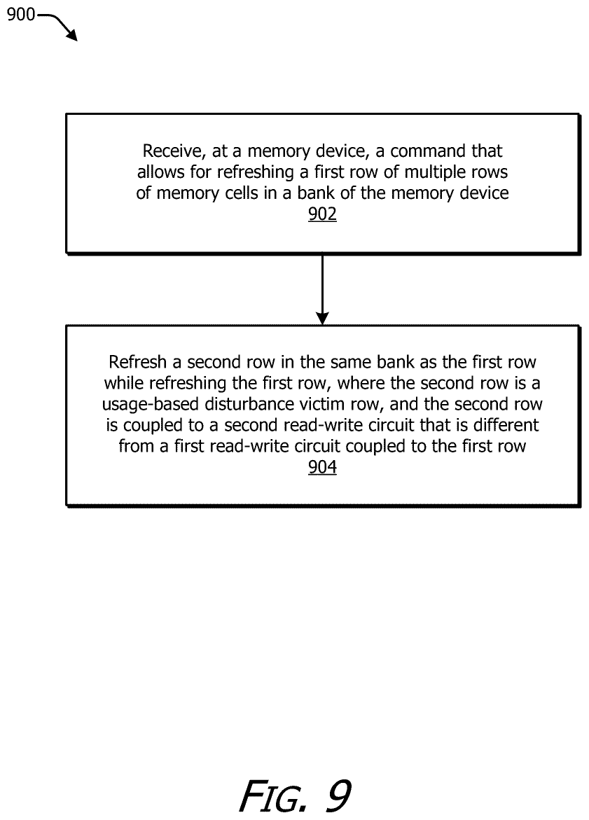

This section describes example methods for implementing sharable usage-based disturbance circuitry with reference to the flow diagram of FIG. 9. These descriptions may also refer to components, entities, and other aspects depicted in FIGS. 1 to 8 by way of example only. The described methods are not necessarily limited to performance by one entity or multiple entities operating on one device.

FIG. 9 illustrates a flow diagram 900, which includes operations 902 and 904. In aspects, operations of the method of the flow diagram 900 are implemented by or with multiple-row refresh circuitry 124 as described with reference to FIG. 1. At 902, a command is received at a memory device. The command allows for refreshing a first row of multiple rows of memory cells in a bank of the memory device. For example, the multiple-row refresh circuitry 124 of FIG. 1 receives the command. The command can be or can be related to a usage-based disturbance mitigation command, a refresh management command, a self-refresh command, an auto-refresh command, a normal refresh command, and/or can be any other command relating to refreshing at least one row in the bank 118. Sometimes the first row is a victim row and the command enables usage-based disturbance to be mitigated for the first row. Other times the first row is not a victim row and the command is associated with normal refreshing of the memory device 108.

At 904, a second row in the same bank 118 as the first row is refreshed while refreshing the first row. The second row is a usage-based disturbance victim row and is coupled to a second read-write circuit that is different from a first read-write circuit coupled to the first row. For example, the multiple-row refresh circuitry 124 refreshes the victim row 120-1 of FIG. 4 while refreshing the normally refreshed row 120-2 in the same bank 118. In an example implementation, the normally refreshed row 120-2 is in a first section 402-4 of the bank 118, where the first section 402-4 includes rows of memory cells that are coupled to the read-write circuit 122-3. The victim row 120-1 is in a second section 402-6 of the bank 118, where the second section 402-6 includes rows of memory cells that are coupled to the read-write circuit 122-6. The first section 402-4 is not immediately adjacent to the second section 402-6. Each row 120-1 and 120-2 can store data associated with usage-based disturbance within a subset of the memory cells. After refreshing the rows 120-1 and 120-2, the multiple-row refresh circuitry 124 can update data associated with usage-based disturbance of the row 120-1 at a different time than updating data associated with usage-based disturbance of the row 120-2.

For the figures described above, the orders in which operations are shown and/or described are not intended to be construed as a limitation. Any number or combination of the described process operations can be combined or rearranged in any order to implement a given method or an alternative method. Operations may also be omitted from or added to the described methods. Further, described operations can be implemented in fully or partially overlapping manners.

Aspects of these methods may be implemented in, for example, hardware (e.g., fixed-logic circuitry or a processor in conjunction with a memory), firmware, software, or some combination thereof. The methods may be realized using one or more of the apparatuses or components shown in FIGS. 1-3, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media includes both non-transitory computer storage media and communication media including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

In the following, various examples for implementing aspects of multiple-row refresh for usage-based disturbance mitigation are described:

Example 1: An apparatus comprising:
a memory device comprising:
   at least one bank comprising multiple rows of memory cells; and
   circuitry coupled to the at least one bank, the circuitry configured to:
      refresh a first row of multiple rows in a bank of the at least one bank while refreshing a second row of the multiple rows in the same bank as the first row, where the first row is a usage-based disturbance victim row, and the first row is coupled to a first read-write circuit that is different from a second read-write circuit coupled to the second row.

Example 2: The apparatus of example 1 or any other example, wherein
the first row is in a first section of the bank, where the first section comprises rows of memory cells that are coupled to the first read-write circuit, and
the second row is in a second section of the bank, where the second section comprises rows of memory cells that are coupled to the second read-write circuit.

Example 3: The apparatus of example 2 or any other example, wherein the first section is not immediately adjacent to the second section.

Example 4: The apparatus of example 2 or any other example, wherein the first read-write circuit comprises:
a set of digit lines coupled to a set of memory cells in the first section of the bank; and
a set of sense amplifiers coupled to the set of digit lines and configured to read data on the digit lines from the set of memory cells within the first section.

Example 5: The apparatus of example 2 or any other example, further comprising usage-based disturbance circuitry configured to identify at least one victim row of the multiple rows that is to be refreshed to mitigate usage-based disturbance within the bank,
wherein the circuitry is configured to:
   determine that an identified victim row of the identified at least one victim row is coupled to a read-write circuit different from the second row based on determining that an address of the identified victim row is in a different, non-neighboring, section of the bank than the second row
refresh the first row as the identified victim row in response to determining the identified victim row is coupled to a read-write circuit different from the second row.

Example 6: The apparatus of example 1 or any other example, wherein the circuitry is configured to:
determine the first row is coupled to a first read-write circuit that is different from the second read-write circuit coupled to the second row; and
refresh the first row while refreshing a second row in response to the determination that the first row is coupled to a first read-write circuit that is different from the second read-write circuit coupled to the second row.

Example 7: The apparatus of example 1 or any other example, wherein the circuitry is configured to:
receive a command that allows for a quantity of refresh operations to be performed in series within the bank;
perform the quantity of refresh operations by at least refreshing the second row; and
perform at least one additional refresh operation by at least refreshing the first row, the performing of the at least one additional refresh occurring during a time interval in which the circuitry performs the quantity of refresh operations.

Example 8: The apparatus of example 1 or any other example, wherein the second row comprises a row that is being refreshed during a periodic refresh operation.

Example 9: The apparatus of example 1 or any other example, wherein
the second row comprises a usage-based disturbance victim row, and
the circuitry is configured to refresh the first row while refreshing a second row in response to receiving a targeted refresh command to refresh the second row based on the second row being a usage-based disturbance victim row.

Example 10: The apparatus of example 1 or any other example, wherein
each row of the multiple rows is configured to store data associated with usage-based disturbance within a subset of the memory cells, and
the circuitry is configured to update data associated with usage-based disturbance of the first row at a different time than updating data associated with usage-based disturbance of the second row.

Example 11: The apparatus of example 10 or any other example, wherein
the data associated with usage-based disturbance comprises an activation count that represents a number of times a corresponding row has been accessed since a last refresh, and
the circuitry is configured to update the data associated with usage-based disturbance by performing an activation count update procedure.

Example 12: The apparatus of example 1 or any other example, wherein the circuitry is configured to:
determine the first row is coupled to a same read-write circuit as the second row; and
abstain from refreshing the first row while refreshing the second row based on the first row being coupled to a same read-write circuit as the second row.

Example 13: The apparatus of example 1 or any other example, wherein the circuitry is configured to refresh a third row of multiple rows in the bank while refreshing the first and second rows, where the third row is a usage-based disturbance victim row, and the third row is coupled to a third read-write circuit that is different from the first and second read-write circuits.

Example 14: A method comprising:
receiving, at a memory device, a command that allows for refreshing a first row of multiple rows of memory cells in a bank of the memory device; and
refreshing a second row in the same bank as the first row while refreshing the first row, where the second row is a usage-based disturbance victim row, and the second row is coupled to a second read-write circuit that is different from a first read-write circuit coupled to the first row.

Example 15: The method of example 14 or any other example, wherein
the first row is in a first section of the bank, where the first section comprises rows of memory cells that are coupled to the first read-write circuit, and
the second row is in a second section of the bank, where the second section comprises rows of memory cells that are coupled to the second read-write circuit.

Example 16: The method of example 15 or any other example, wherein the first section is not immediately adjacent to the second section.

Example 17: The method of example 15 or any other example, further comprising:
identifying at least one victim row of the multiple rows that is to be refreshed to mitigate usage-based disturbance within the bank; and
determining that an identified victim row of the identified at least one victim row is coupled to a read-write circuit different from the first row based on determining that an address of the identified victim row is in a different, non-neighboring, section of the bank than the second row,
wherein refreshing comprises refreshing the first row as the identified victim row in response to determining the identified victim row is coupled to a read-write circuit different from the first row.

Example 18: The method of example 14 or any other example, wherein
each row of the multiple rows is configured to store data associated with usage-based disturbance within a subset of the memory cells, and
the method comprises updating data associated with usage-based disturbance of the first row at a different time than updating data associated with usage-based disturbance of the second row.

Example 19: An apparatus comprising:
a memory device comprising:
   at least one bank comprising multiple rows of memory cells; and
   circuitry coupled to the at least one bank, the circuitry configured to:
      receive a command that allows for a number of refresh operations to be performed in series within a bank of the at least one bank;
      perform at least one refresh operation of the number of refresh operations by refreshing a first row of multiple rows in the bank, where the first row is coupled to a first read-write circuit; and
      perform at least one additional refresh operation by at least refreshing a second row of multiple rows in the bank, where the second row is a usage-based disturbance victim row and is coupled to a second read-write circuit that is different from the first read-write circuit,
where the performing of the at least one additional refresh occurs during a time interval in which the circuitry performs the at least one refresh operation of the number of refresh operations.

Example 20: The apparatus of example 19 or any other example, wherein
each row of the multiple rows is configured to store data associated with usage-based disturbance within a subset of the memory cells, and
the circuitry is configured to update data associated with usage-based disturbance of the first row at a different time than updating data associated with usage-based disturbance of the second row.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### CONCLUSION

Although aspects of implementing multiple-row refresh for usage-based disturbance mitigation have been described in language specific to certain features and/or methods, the subject of the appended claims is not necessarily limited to the specific features or methods described. Rather, the specific features and methods are disclosed as a variety of example implementations of implementing multiple-row refresh for usage-based disturbance mitigation.

What is claimed is:

1. An apparatus comprising:
a memory device comprising:
at least one bank comprising multiple rows of memory cells; and
circuitry coupled to the at least one bank, the circuitry configured to:
refresh a first row of multiple rows in a bank of the at least one bank while refreshing a second row of the multiple rows in the same bank as the first row, where the first row is a usage-based disturbance victim row, and the first row is coupled to a first read-write circuit that is different from a second read-write circuit coupled to the second row.

2. The apparatus of claim 1, wherein
the first row is in a first section of the bank, where the first section comprises rows of memory cells that are coupled to the first read-write circuit, and
the second row is in a second section of the bank, where the second section comprises rows of memory cells that are coupled to the second read-write circuit.

3. The apparatus of claim 2, wherein the first section is not immediately adjacent to the second section.

4. The apparatus of claim 2, wherein the first read-write circuit comprises:
a set of digit lines coupled to a set of memory cells in the first section of the bank; and
a set of sense amplifiers coupled to the set of digit lines and configured to read data on the digit lines from the set of memory cells within the first section.

5. The apparatus of claim 2, further comprising usage-based disturbance circuitry configured to identify at least one victim row of the multiple rows that is to be refreshed to mitigate usage-based disturbance within the bank,
wherein the circuitry is configured to:
determine that an identified victim row of the identified at least one victim row is coupled to a read-write circuit different from the second row based on determining that an address of the identified victim row is in a different, non-neighboring, section of the bank than the second row
refresh the first row as the identified victim row in response to determining the identified victim row is coupled to a read-write circuit different from the second row.

6. The apparatus of claim 1, wherein the circuitry is configured to:
determine the first row is coupled to a first read-write circuit that is different from the second read-write circuit coupled to the second row; and
refresh the first row while refreshing a second row in response to the determination that the first row is coupled to a first read-write circuit that is different from the second read-write circuit coupled to the second row.

7. The apparatus of claim 1, wherein the circuitry is configured to:
receive a command that allows for a quantity of refresh operations to be performed in series within the bank;
perform the quantity of refresh operations by at least refreshing the second row; and
perform at least one additional refresh operation by at least refreshing the first row, the performing of the at least one additional refresh occurring during a time interval in which the circuitry performs the quantity of refresh operations.

8. The apparatus of claim 1, wherein the second row comprises a row that is being refreshed during a periodic refresh operation.

9. The apparatus of claim 1, wherein
the second row comprises a usage-based disturbance victim row, and
the circuitry is configured to refresh the first row while refreshing a second row in response to receiving a targeted refresh command to refresh the second row based on the second row being a usage-based disturbance victim row.

10. The apparatus of claim 1, wherein
each row of the multiple rows is configured to store data associated with usage-based disturbance within a subset of the memory cells, and
the circuitry is configured to update data associated with usage-based disturbance of the first row at a different time than updating data associated with usage-based disturbance of the second row.

11. The apparatus of claim 10, wherein
the data associated with usage-based disturbance comprises an activation count that represents a number of times a corresponding row has been accessed since a last refresh, and
the circuitry is configured to update the data associated with usage-based disturbance by performing an activation count update procedure.

12. The apparatus of claim 1, wherein the circuitry is configured to:
determine the first row is coupled to a same read-write circuit as the second row; and
abstain from refreshing the first row while refreshing the second row based on the first row being coupled to a same read-write circuit as the second row.

13. The apparatus of claim 1, wherein the circuitry is configured to refresh a third row of multiple rows in the bank while refreshing the first and second rows, where the third row is a usage-based disturbance victim row, and the third row is coupled to a third read-write circuit that is different from the first and second read-write circuits.

14. A method comprising:
receiving, at a memory device, a command that allows for refreshing a first row of multiple rows of memory cells in a bank of the memory device; and
refreshing a second row in the same bank as the first row while refreshing the first row, where the second row is a usage-based disturbance victim row, and the second row is coupled to a second read-write circuit that is different from a first read-write circuit coupled to the first row.

15. The method of claim 14, wherein
the first row is in a first section of the bank, where the first section comprises rows of memory cells that are coupled to the first read-write circuit, and
the second row is in a second section of the bank, where the second section comprises rows of memory cells that are coupled to the second read-write circuit.

16. The method of claim 15, wherein the first section is not immediately adjacent to the second section.

17. The method of claim 15, further comprising:
identifying at least one victim row of the multiple rows that is to be refreshed to mitigate usage-based disturbance within the bank; and
determining that an identified victim row of the identified at least one victim row is coupled to a read-write circuit different from the first row based on determining that an address of the identified victim row is in a different, non-neighboring, section of the bank than the second row,
wherein refreshing comprises refreshing the first row as the identified victim row in response to determining the identified victim row is coupled to a read-write circuit different from the first row.

18. The method of claim 14, wherein
each row of the multiple rows is configured to store data associated with usage-based disturbance within a subset of the memory cells, and
the method comprises updating data associated with usage-based disturbance of the first row at a different time than updating data associated with usage-based disturbance of the second row.

19. An apparatus comprising:
a memory device comprising:
at least one bank comprising multiple rows of memory cells; and
circuitry coupled to the at least one bank, the circuitry configured to:
receive a command that allows for a number of refresh operations to be performed in series within a bank of the at least one bank;
perform at least one refresh operation of the number of refresh operations by refreshing a first row of multiple rows in the bank, where the first row is coupled to a first read-write circuit; and
perform at least one additional refresh operation by at least refreshing a second row of multiple rows in the bank, where the second row is a usage-based disturbance victim row and is coupled to a second read-write circuit that is different from the first read-write circuit,
where the performing of the at least one additional refresh occurs during a time interval in which the circuitry performs the at least one refresh operation of the number of refresh operations.

20. The apparatus of claim 19, wherein
each row of the multiple rows is configured to store data associated with usage-based disturbance within a subset of the memory cells, and
the circuitry is configured to update data associated with usage-based disturbance of the first row at a different time than updating data associated with usage-based disturbance of the second row.
